(19) United States
(12) Patent Application Publication
(10) Pub. No.: US 2021/0098674 A1
(43) Pub. Date: Apr. 1, 2021

(54) ACTIVE MATERIAL AND ELECTRIC POWER GENERATOR CONTAINING IT

(71) Applicant: TERMO-IND SA, Chiasso (CH)

(72) Inventors: Luca MAGAGNIN, Rho (IT); Simona IEFFA, Valmorea (IT); Alessandra ACCOGLI, Diso (IT); Gabriele PANZERI, Cornate D'Adda (IT); Francesco LIBERALE, Pavia (IT); Vincenzo TIRELLA, Coldrerio (CH); Eugenio GIBERTINI, Cusago (IT); Luca SUCCA, Roma (IT); Simone BRUNETTI, Roma (IT)

(21) Appl. No.: 16/956,644

(22) PCT Filed: Dec. 20, 2018
(86) PCT No.: PCT/EP2018/086344

§ 371 Date: Jun. 22, 2020

(30) Foreign Application Priority Data
Dec. 20, 2017 (EP) PCT/EP2017/083786

(51) Int. Cl. H01L 35/22; H02K 7/18; H02P 9/48

(52) U.S. Cl. CPC H01L 35/22; H02P 9/48; H02K 7/1823

(57) ABSTRACT

The invention relates to an electric power generator (EPG) comprising at least a first electrode (11) and a second electrode (12), wherein the electric power generator comprises an active material between said electrodes (11,12), said active material comprising at least one oxygen-containing compound selected from the group consisting of MgO, ZnO, ZrOCl₂, ZrO₂, SiO₂, Bi₂O₃, FeO₃O₄, AI₂O₃, TiO₂, BₑO, CaO, Ga₂O₃, In₂O₃, GeO₂, SnO₂ and PbO₂, wherein the particle size of the oxygen-containing compound has an average diameter in the range from 10 nm to 40 μm at and wherein a thickener additive selected from the group consisting of agar agar, xanthan gum, methyl cellulose, and arabic gum is absent

### FIELD OF THE INVENTION

The present invention relates to an active material to be used for the manufacturing of an electric generator and to a method for obtaining such medium. The present invention hence relates also to an electric generator comprising said active material.

### STATE OF THE ART

It is widely known the use of thermoelectric power generators and thermionic power generators for the conversion of thermal energy directly into electrical energy. The thermoelectric power generators are devices based on a thermoelectric effect, namely the Seebeck effect, involving interactions between the flow of heat and of electricity between solid bodies. Examples of such devices are disclosed in the patent EP 2521192 and in the patent application EP 2277209. In broad terms, thermoelectric power generators consist of three main components: thermoelectric material, thermoelectric modules and thermoelectric system that interface with a heat source.

Thermoelectric materials generate power directly from heat by converting temperature differences into electric voltage. In particular, these materials typically have both high electrical conductivity and low thermal conductivity. The low thermal conductivity ensures that when one side is made hot, the other side stays cold. This helps to generate a large voltage while in a temperature gradient.

A thermoelectric module is a circuit containing thermoelectric materials which generate electricity from heat directly. A module consists of two dissimilar thermoelectric materials joining at their ends, namely a negatively charged semiconductor and a positively charged semiconductor. A direct electric current will flow in the circuit when there is a temperature gradient between the two materials. Such gradient is provided by the thermoelectric system which typically comprise heat exchangers used on both sides on the module to supply respectively heating and cooling.

A thermionic power generators, also called thermionic power converters, convert heat directly into electricity. A thermionic power generator typically comprises two electrodes arranged in a containment. One of these is raised to a sufficiently high temperature to become a thermionic electron emitter or “hot plate”. The other electrode is called collector because it receives the emitted electrons. The collector is operated at significantly lower temperature. The space between the electrodes can be vacuum or alternatively filled with a vapour gas at low pressure. The thermal energy may be supplied by chemical, solar or nuclear sources.

Thermoelectric power generators as well as thermionic power generators have many drawbacks, among which the low conversion efficiency and the need of providing a temperature gradient. In addition, such generators, requires relatively constant thermal source.

Therefore, it is the primary object of the present invention to provide an electric power generator capable to convert part of the thermal energy in electric energy and allowing to overcome the drawbacks of the devices of the prior art.

In the International application PCT/EP2017/069925, not yet published, it is already described an active material capable to be applied on one electrode and to generate current when comprised between at least two electrodes, surprisingly without initial charging and dependently on the temperature. Specifically, the material described in PCT/EP2017/069925 comprises at least one oxygen-containing compound selected from the group consisting of MgO, ZnO, ZrOCl₂, ZrO₂, SiO₂, Bi₂O₃, Al₂O₃ and TiO₂, at least one thickener additive selected from the group consisting of agar agar, xanthan gum, methyl cellulose, and arabic gum, and at least one plasticizer additive, wherein the particle size of the oxygen-containing compound has a specific average diameter.

The inventors found out that the performances of the active material were worse in the presence of temperatures above 80° C., and that the temperature above 90° C. induced the degradation of the active material with lowering of the device performances and the decrease of stability of the final device.

A further object of the invention is therefore to provide an electric generator capable to provide electric energy in a wide range of temperatures.

A still further object is hence to provide an electric device capable to generate electric energy having also high stability to temperature.

### SUMMARY OF THE INVENTION

The inventors surprisingly found out that they can provide a new active material capable to be applied on one electrode and to generate current when comprised between at least two electrodes without initial charging and dependently on the temperature without the disadvantages of the prior art devices.

Therefore the invention relates to an electric power generator (EPG) comprising at least two electrodes, placed at a suitable distance from each other and preferably made of different material, comprising between said electrodes an active material comprising at least one oxygen-containing compound selected from the group consisting of MgO, ZnO, ZrOCl₂, ZrO₂, SiO₂, Bi₂O₃, Fe₃O₄, Al₂O₃, TiO₂, BeO, CaO, Ga₂O₃, In₂O₃, GeO₂, SnO₂ and PbO₂, wherein the particle size of the oxygen-containing compound has an average diameter in the range from 10 nm to 40 μm and wherein a thickener additive selected from the group consisting of agar agar, xanthan gum, methyl cellulose, and arabic gum is absent.

Specifically, the inventors found out that they have to eliminate the thickener additive in order to overcome the disadvantages of the devices of the prior art. Therefore, the inventors propose a new substantially dry state device, as alternative and improvement respect to the devices of the prior art.

In a preferred embodiment a cellulose compound as a thickener agent is further absent in the active material of the invention. In a further preferred and advantageous embodiment, the at least one oxygen-containing compound selected from the group consisting of MgO, ZnO, ZrOCl₂, ZrO₂, SiO₂, Bi₂O₃, Fe₃O₄, Al₂O₃, TiO₂, BeO, CaO, Ga₂O₃, In₂O₃, GeO₂, SnO₂ and PbO₂ or a mixture thereof is in an amount in the range from 0.6% to 100% (w/w) with respect to the amount of the active material, more preferably in an amount in the range from 1% to 80%, still more preferably 50-80% (w/w).

The active material of the EPG of the invention can hence be anhydrous or can contain a certain amount of water, as coordinated water molecules to the oxygen-containing compound, deriving from the process for preparing the active material: the inventors deem that such coordinated water in the final active material can ameliorate the performances of the final devices obtained by incorporating the active material. The oxygen-containing compound can contain coordinated water in the range from 0.5% by weight to 7.5% by weight with respect to oxygen-containing compound preferably from 0.5% to 3.5%, more preferably from 0.5% to 1.5%.

Without being bound to any theory the inventors deem that thickener additives used in the prior art are organic materials used to increase the viscosity of a liquid dispersion. However, the inventors found out that these materials have intrinsic low thermal stability induced by the reversibility of gelification process if a temperature higher than their melting temperature was applied. For example, agar agar gels and melts respectively at 40° C. and 80° C. and methylcellulose at 62° C. and 68° C. respectively.

Consequently, the exposition of these materials to high temperatures induced active material degradation and hence worsen the stability of the final device.

According to the present invention the EPG is capable to provide electric energy in a wide range of temperatures.

The invention also provides an electric device capable to generate electric energy having also high stability to temperature.

In a preferred embodiment of the invention the active material comprises MgO, ZnO and ZrO₂ as powder as oxygen-containing compounds.

Therefore, the EPG according to the invention comprises oxygen-containing compounds between the at least two electrodes. The electrodes are made of metals, alloys and/or carbon-based materials like graphite. Electrodes thickness ranges preferably from 0.1 to 3000 μm, more preferably from 50 to 1000 μm, still more preferably from 300 to 600 μm. In another embodiment of the invention, these electrodes are made of powders with particle average diameter in the range from 10 nm to 40 μm, preferably in the range of 10 nm to 20 μm, more preferably 10-100 nm. In a preferred embodiment of the EPG according to the invention, the at least two electrodes are made of Al and graphite, in form of foil and powder respectively. In case of flexible EPG both self-standing flexible materials (among the previous listed materials) and metallized polymers can be considered as electrodes. The inventors do not exclude the possibility to recharge the EPG applying a voltage to the EPG at a constant temperature or during a thermal path.

The present invention also relates to a power generator module (PWG) comprising a plurality of EPG which can be connected in series or parallel without compromising the EPG characteristics (voltage and current).

### DESCRIPTION OF FIGURES

Further features and advantages of the invention will be more apparent in light of the detailed description of the active material and of the preferred embodiments of the electric power generator with the aid of enclosed drawings in which:

FIG. 1 shows the structure of an electric power generator (EPG) according to the present invention;

FIGS. 1A and 1B show respectively a first embodiment and a second embodiment of a power generator module (PGM) comprising a plurality of EPG according to the present invention;

FIGS. 2A and 2B show an electrical circuit, in two different operative configurations, used for the electrical characterization of an EPG according to the invention;

FIG. 3 shows an electrical circuit usable for the electrical characterization of a PGM comprising a plurality of EPG according to the invention;

FIG. 4 shows an electrical circuit used for the electrical characterization of example 10;

FIG. 5 shows the results of electrical characterization of example 10;

FIG. 6 shows an electrical circuit used for the electrical characterization of example 11;

FIG. 7 shows the results of electrical characterization of example 11;

FIGS. 8 and 9 show the results of electrical characterization of example 12;

FIG. 10 shows the results of electrical characterization of example 13;

FIG. 11 shows the electrical circuit used for the electrical characterization of example 14; and

FIG. 12 shows the results of electrical characterization of example 14.

### DETAILED DESCRIPTION OF THE INVENTION

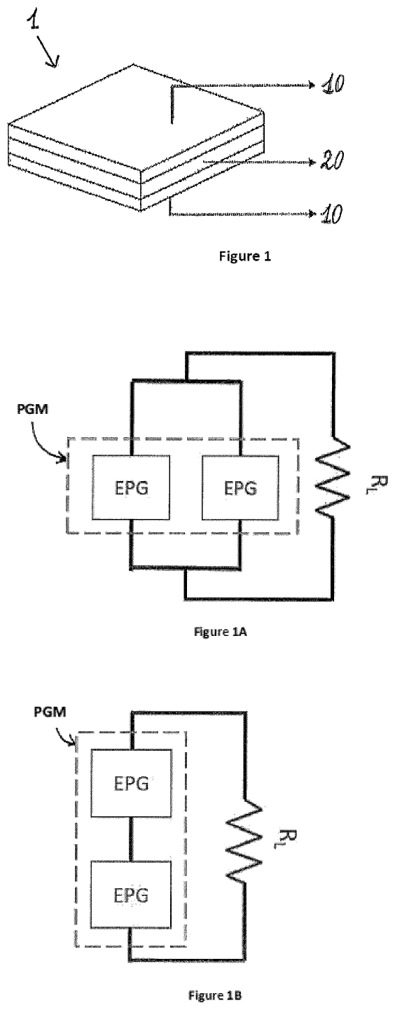

The invention hence relates to an electric power generator (EPG) comprising at least two electrodes 10, placed at a suitable distance from each other and preferably made of different material, comprising an active material 20 between said electrodes 10. The structure of an EPG is shown in FIG. 1. According to the invention, said active material comprises at least one oxygen-containing compound selected from the group consisting of MgO, ZnO, ZrOCl₂, ZrO₂, SiO₂, Bi₂O₃, Fe₃O₄, Al₂O₃, TiO₂, BeO, CaO, Ga₂O₃, In₂O₃, GeO₂, SnO₂ and PbO₂, wherein the particle size of the oxygen-containing compound has an average diameter in the range from 10 nm to 40 μm and wherein a thickener additive selected from the group consisting of agar agar, xanthan gum, methyl cellulose and arabic gum is absent.

In a preferred embodiment a cellulose compound as a thickener agent is further absent in the active material of the invention.

In a further preferred and advantageous embodiment, the at least one oxygen-containing compound selected from the group consisting of MgO, ZnO, ZrOCl₂, ZrO₂, SiO₂, Bi₂O₃, Fe₃O₄, Al₂O₃, TiO₂, BeO, CaO, Ga₂O₃, In₂O₃, GeO₂, SnO₂ and PbO₂ or a mixture thereof is in an amount in the range from 0.6% to 100% (w/w) with respect to the amount of the active material, more preferably in an amount in the range from 1% to 80%, still more preferably 50-80% (w/w).

The active material of the EPG of the invention could comprises also at least one plasticizer additive. The at least one plasticizer additive is preferably selected from the group consisting of siloxanes, Carnauba Wax, Naphtalene, PVDF, Parylene, PTFE, FEP, PDMS, aqueous based polymers and bio-polymers.

The active material can comprise further compounds as additive, preferably Antrachene, PZT materials, and Si₃N₄.

It is reasonably thought that the combined use of these materials with the oxygen-containing compounds of the invention could enhance the performances of the device or, at least, improve the results obtained under particular regimes.

The active material of the EPG of the invention can be anhydrous or can contain a certain amount of the water, as coordinated water molecules, deriving from the process for preparing it: the inventors deem that such coordinated water in the final active material can ameliorate the performances of the final devices obtained by incorporating the active material. The oxygen-containing compound can contain coordinated water in the range from 0.5% by weight to 7.5% by weight with respect to oxygen-containing compound preferably from 0.5% to 3.5%, more preferably from 0.5% to 1.5%.

Particles of oxygen-based compounds of the active material have an average diameter in the range from 5 nm to 40 μm, preferably 15 nm-10 μm, more preferably 20 nm-5 μm. In another advantageous and preferred aspect of the invention, the particles of oxygen-based compounds have an average diameter in the range from 10-200 nm, more preferably in the range of 15-100 nm, still more preferably 20-40 nm.

The active material of the EPG of the invention comprises preferably magnesium oxide as oxygen-containing compound, more preferably in the weight percentage in the range from 0.6% and 100%, preferably from 1% to 100%, more preferably from 50% to 80% with respect to the total weight of the active material.

The active material comprises preferably zirconium oxide as oxygen-containing compound, more preferably in the weight percentage in the range from 0.6% and 100%, preferably from 1% to 100%, more preferably from 50% to 80% with respect to the total weight of the active material.

The active material preferably comprises MgO with ZrO₂ as oxygen-containing compounds, more preferably in the weight percentage in the range from 0.6% and 100%, still more preferably in the range of 5% and 80% with respect to the total weight of the active material.

The active material preferably comprises MgO together with both ZnO and ZrO₂ as oxygen-containing compounds, more preferably each one in the weight percentage in the range from 0.6% and 90%, still more preferably in the range of 5% and 80% with respect to the total weight of the active material.

The EPG of the invention comprises the active material between the at least two electrodes.

The oxygen-based compounds of the active material can be placed as powder on at least one electrode and pressed against the other metal electrode using a machine press. Alternative techniques already known in the art can be used, for example sol-gel, inkjet printing and sputtering.

The electrodes are made of metals, alloys and/or carbon-based materials like graphite. Electrodes thickness ranges preferably from 0.1 to 3000 μm, more preferably from 50 to 1000 μm, still more preferably from 300 to 600 μm. In a preferred embodiment of the EPG according to the invention, the at least two electrodes are made of Cu and Al, preferably in form of plates or foils substantially parallel. In case of flexible EPG both self-standing flexible materials (among the previous listed materials) and metallized polymers can be considered as electrodes.

In a preferred embodiment of the EPG 1 schematically shown in FIG. 1, the at least two electrodes 10 have a plate-shape. The two plates are arranged substantially parallel each other so as to define a gap filled with the active material 20 of the invention according to a “sandwich structure”. The distance of the electrodes 10 depends directly on the desired thickness of the active material to be applied.

The shape of the electrodes is not binding. In an alternative embodiment, for example, the EPG could comprise two coaxial cylindrical electrodes that define an annular space filled with the active material according to the invention. According to the invention, the EPG could comprise more than two electrodes wherein two adjacent electrodes define a gap filled with the active material.

According to a preferred embodiment, the at least two electrodes are made of different material, preferably of Cu and Al. The two at least electrodes are preferably subjected to cleaning and etching prior to be used in the electric power generator of the invention.

The active material of the EPG of the invention is preferably applied on the electrode, by depositing the active material in a thickness from 100 nm to 5 mm. On the other hand, the optimal thickness varies depending on applications. In a further aspect, the invention relates to a power generator module (PGM) comprising a plurality of EPG which can be connected in series or parallel. On this regards, FIG. 1A shows a circuit comprising a PGM wherein the two EPG are connected in parallel, while FIG. 1B shows a circuit comprising a PGM having two EPG connected in series. Both the circuits of FIGS. 1A and 1B comprise a load resistance R_{L}. The voltage relative to the PGM can be monitored, for example, by connecting a potentiostat/galvanostat parallel to the load resistance R_{L}.

The active material of the EPG according to the invention can be prepared preferably by pressing the powders of the one or more oxygen-containing compounds having the average diameter according to the invention. The pressing step can be preferably carried out directly on one of the two electrodes of the EPG of the invention.

Alternatively, the active material can be deposited as a composition on one of the two electrodes and after subjected to a baking step in order to obtain a substantially dry product.

Without being bound to any theory the inventors deem that fluxing different selected gaseous species during the preparation procedure of the active material could enhance the final performances of the as obtained EPG, in terms of open circuit voltage (OCV), according to the series N₂>Air (wet)>Air (dry)>O₂ (dry)>CO₂ (dry).

In another aspect of the invention, inventors deem that the proposed active material contained in the EPG of the invention could be reasonably integrated in the mix of active materials adopted for the manufacturing of commonly used capacitors. Therefore in another aspect the invention concerns the use of an active material comprising at least one oxygen-containing compound selected from the group consisting of MgO, ZnO, ZrOCl₂, ZrO₂, SiO₂, Bi₂O₃, Fe₃O₄, Al₂O₃, TiO₂, BeO, CaO, Ga₂O₃, In₂O₃, GeO₂, SnO₂ and PbO₂, wherein the particle size of the oxygen-containing compound has an average diameter in the range from 10 nm to 40 μm and wherein a thickener additive selected from the group consisting of agar agar, xanthan gum, methyl cellulose, and arabic gum is absent for manufacturing capacitors.

In a further aspect the invention relates to a capacitor comprising at least a first electrode, a second electrode and an active material comprising at least one oxygen-containing compound selected from the group consisting of MgO, ZnO, ZrOCl₂, ZrO₂, SiO₂, Bi₂O₃, Fe₃O₄, Al₂O₃, TiO₂, BeO, CaO, Ga₂O₃, In₂O₃, GeO₂, SnO₂ and PbO₂, wherein the particle size of the oxygen-containing compound has an average diameter in the range from 10 nm to 40 μm and wherein a thickener additive selected from the group consisting of agar agar, xanthan gum, methyl cellulose, and arabic gum is absent.

In a preferred embodiment a cellulose compound as a thickener agent is further absent in the active material of the invention.

In a further preferred and advantageous embodiment, the at least one oxygen-containing compound selected from the group consisting of MgO, ZnO, ZrOCl₂, ZrO₂, SiO₂, Bi₂O₃, Fe₃O₄, Al₂O₃, TiO₂, BeO, CaO, Ga₂O₃, In₂O₃, GeO₂, SnO₂ and PbO₂ or a mixture thereof is in an amount in the range from 0.6% to 100% (w/w) with respect to the amount of the active material, more preferably in an amount in the range from 1% to 80%, still more preferably 50-80% (w/w).

The preferred features relating to EPG according to the invention can be the same for the capacitor according to the invention in view of the same technical peculiarities.

As it will be evident from the following experimental part the EPG of the invention is capable to generate current as soon as it has been assembled, thus being a different device from a conventional capacitor. Furthermore and surprisingly, the performances of the EPG of the invention have a strongly dependence on temperature, i.e. potential difference increases with the temperature. In particular, with respect to the traditional power generators of the prior art, the EPG according to the invention does not require a temperature gradient. Indeed, the electric power generator of the invention is capable to convert part of the thermal energy in electric energy even an isotherm condition. Specifically and advantageously, the current measured by the electric power generator of the invention is increased by a factor of 1.5-4, increasing the temperature from 20 to 80° C.

According to the present invention the EPG is advantageously capable to provide electric energy in a wide range of temperatures. Advantageously, the electric energy provided by the EPG has high stability to temperature.

The EPG of the invention was characterized by the electric point of view. First, the open circuit voltage (OCV) was measured by means of a multimeter, the EPG device showed a voltage of 1 V in the configuration comprising aluminum and graphite as electrodes and a mixture of oxides with MgO as major component. Other EPG devices according to the invention were prepared and depending on the components, electrodes and powders materials, the results varied from 50 mV to 1200 mV.

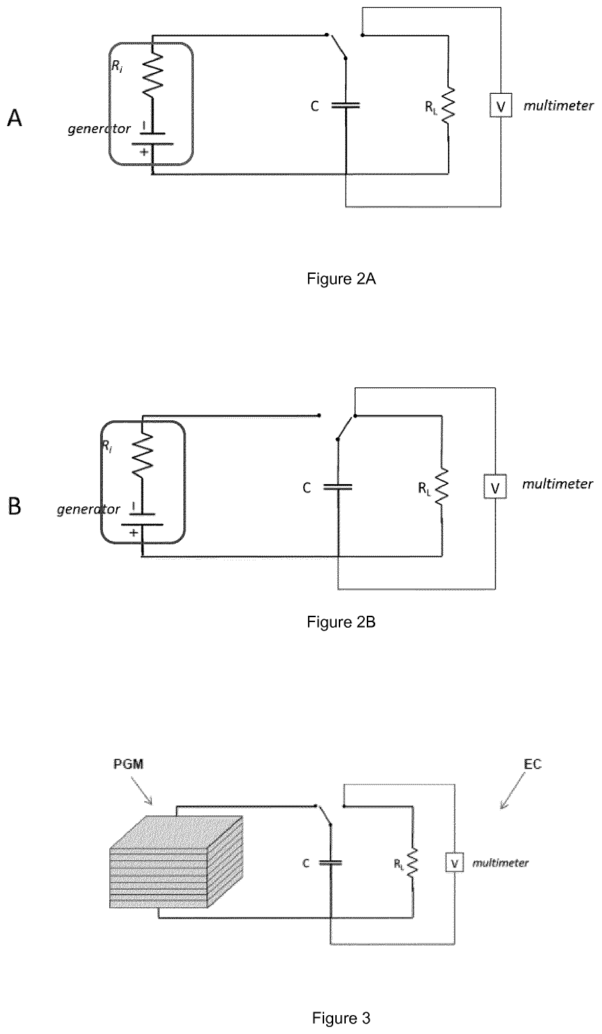

With reference to FIGS. 2A and 2B. A dedicated electrical circuit EC was selected in order to characterize the EPG from the electrical point of view. In particular, EPG based on mixed oxides powder were tested. As shown in the circuit in FIG. 2A the EPG was connected in series with a capacitor C with initial voltage Vi=0 V. More precisely, the electrical circuit EC comprises a switch SW that connected the EPG to the capacitor C in a first switching state. During a charge phase (FIG. 2A), the EPG charged the capacitor up to an equilibrium voltage. Once the capacitor was charged, the switch SW was activated (in a second switching state), thus connecting the capacitor to an arbitrary load resistor R_{L} for discharging the capacitor (discharge phase or rest phase); the EPG was now electrically isolated (FIG. 2B). With the term resistor is generally meant an electric resistor, a diode, a combination thereof, or any electrical component able to discharge the capacitor C when the switch SW is in said second switching state.

The energy stored in the capacitor was calculated from characteristic capacity and the charged voltage (Vc), measured by means of a multimeter; preferably an electrochemical capacitor was employed in this setup. In one of the test carried out, a temporized switch was used to alternate charge of the capacitor and the rest phase where the EPG was electrically isolated, in this phase voltage cell recover occurred. During this phase (FIG. 2B) the capacitor connected in series with an arbitrary resistor (RL) with the only purpose to discharge it completely prior the beginning of the next charge cycle, the discharge curve was monitored by means of a multimeter.

FIG. 3 shows a PGM in the same testing electrical circuit as in FIG. 2.

The invention will now be illustrated by some not limitative examples of the active material and EPG of the invention.

### EXAMPLES

### Example 1

### Preparation of an EPG of the Invention

In a typical procedure, aluminum foil of thickness of about 100 μm is placed at the bottom of a circle-shaped mold of 2 cm diameter. 0.1 g of MgO powder with average diameter in the range from 10 nm to 40 μm, preferably in the range of 1-10 μm, more preferably 2-5 μm as sold by Sigma-Aldrich is sprinkled on Al and gently pressed with a piston at 0.01 MPa to compact the active powder. Graphite powder (100 μm mesh, 0.05 g) or copper powder (20 μm mesh, 0.03 g) are then sprinkled on the active material and the mold is removed. Finally, a compressive stress of 800 MPa is applied for 5 minutes and then released. The as-obtained pills, have diameter of 2 cm, thickness of 0.05 cm and weight of 0.35 g.

Without being bound to any theory the inventors deem that fluxing different selected gaseous species during the preparation procedure could enhance the final performances of the as obtained EPG, in terms of OCV, according to the series N₂>Air (wet)>Air (dry)>O₂ (dry)>CO₂ (dry).)

### Example 2

### Preparation of an EPG of the Invention

In a typical procedure, aluminum foil of thickness of about 100 μm is placed at the bottom of a circle-shaped mold of 1.5 cm diameter. 0.1 g of ZrO₂ powder with average diameter in the range from 10 nm to 40 μm, preferably in the range of 1-10 μm, more preferably 2-5 μm as sold by Sigma-Aldrich is sprinkled on Al and gently pressed with a piston at 0.01 MPa to compact the active powder. Copper foil (50 μm of thickness and 1.5 cm of diameter) or copper powder (20 μm mesh, 0.03 g) are then sprinkled on the active material and the mold is removed. Finally, a compressive stress of 800 MPa is applied for 5 minutes and then released. The as-obtained pills have diameter of 1.5 cm and an active area of 1.76 cm².

Without being bound to any theory the inventors deem that fluxing different selected gaseous species during the preparation procedure could enhance the final performances of the as obtained EPG, in terms of OCV, according to the series N₂>Air (wet)>Air (dry)>O₂ (dry)>CO₂ (dry).

### Example 3

### Preparation of an EPG of the Invention

In a typical procedure, aluminum foil of thickness of about 100 μm is placed at the bottom of a circle-shaped mold of 1.5 cm diameter. 0.1 g of MgO powder with average diameter in the range from 10 nm to 40 μm, preferably in the range of 1-10 μm, more preferably 2-5 μm as sold by Sigma-Aldrich is sprinkled on Al and gently pressed with a piston at 0.01 MPa to compact the active powder. Copper foil (50 μm of thickness and 1.5 cm of diameter) or copper powder (20 μm mesh, 0.03 g) are then sprinkled on the active material and the mold is removed. Finally, a compressive stress of 800 MPa is applied for 5 minutes and then released. The as-obtained pills, have diameter of 1.5 cm and an active area of 1.76 cm².

Without being bound to any theory the inventors deem that fluxing different selected gaseous species during the preparation procedure could enhance the final performances of the as obtained EPG, in terms of OCV, according to the series N₂>Air (wet)>Air (dry)>O₂ (dry)>CO₂ (dry).

### Example 4

### Preparation of an EPG of the Invention

In a typical procedure, aluminum foil of thickness of about 100 μm is placed at the bottom of a circle-shaped mold of 1.5 cm diameter. 0.1 g of In₂O₃ powder with average diameter in the range from 10 nm to 40 μm, preferably in the range of 1-10 μm, more preferably 2-5 μm as sold by Sigma-Aldrich is sprinkled on Al and gently pressed with a piston at 0.01 MPa to compact the active powder. Copper foil (50 μm of thickness and 1.5 cm of diameter) or copper powder (20 μm mesh, 0.03 g) are then sprinkled on the active material and the mold is removed. Finally, a compressive stress of 800 MPa is applied for 5 minutes and then released. The as-obtained pills, have diameter of 1.5 cm and an active area of 1.76 cm².

Without being bound to any theory the inventors deem that fluxing different selected gaseous species during the preparation procedure could enhance the final performances of the as obtained EPG, in terms of OCV, according to the series N₂>Air (wet)>Air (dry)>O₂ (dry)>CO₂ (dry).

### Example 5

### Preparation of an EPG of the Invention

In a typical procedure, aluminum foil of thickness of about 100 μm is placed at the bottom of a circle-shaped mold of 1.5 cm diameter. 0.1 g of GeO₂ powder with average diameter in the range from 10 nm to 40 μm, preferably in the range of 1-10 μm, more preferably 2-5 μm as sold by Sigma-Aldrich is sprinkled on Al and gently pressed with a piston at 0.01 MPa to compact the active powder. Copper foil (50 μm of thickness and 1.5 cm of diameter) or copper powder (20 μm mesh, 0.03 g) are then sprinkled on the active material and the mold is removed. Finally, a compressive stress of 800 MPa is applied for 5 minutes and then released. The as-obtained pills, have diameter of 1.5 cm and an active area of 1.76 cm².

Without being bound to any theory the inventors deem that fluxing different selected gaseous species during the preparation procedure could enhance the final performances of the as obtained EPG, in terms of OCV, according to the series N₂>Air (wet)>Air (dry)>O₂ (dry)>CO₂ (dry).

### Example 6

### Preparation of an Active Material for an EPG of the Invention

In a typical procedure, PVDF (polyvininyldene fluoride) flakes (or powder) were mixed to NMP (N-methyl-2-pyrrolidone) solvent and stirred for a range time comprised in the range from 12 h to 48 h, until a complete solute dissolution was reached. In a preferred embodiment, to fasten PVDF dissolution temperature could be raised up to maximum of 80° C.

PVDF content in the solution was at least 0.5%, preferably in the range from 4% to 10% with respect to the total weight.

After this step, oxide powders with average diameter of average diameter in the range from 10 nm to 40 μm, preferably in the range of 1-10 μm, more preferably 2-5 μm as sold by Sigma-Aldrich were added in amount of at least 0.6%, preferably from 10% to 30% with respect to the total weight of the active material. The as obtained mixture had a viscosity value preferably comprised in the range from 1000 cPa to 10000 cPa, more preferably from 5000 cPa to 7000 cPa, as measured with the rotatory viscometer Viscotester VTRS at rpm=20 at T=25° C.

The composition is reported in the following table.

| Chemical | Amount [g] |
|---|---|
| NMP | 72 |
| PVDF | 8 |
| MgO | 15 |
| ZrO₂ | 5 |

Without being bound to any theory the inventors deem that fluxing different selected gaseous species during the preparation procedure could enhance the final performances of the as obtained EPG, in terms of OCV, according to the series N₂>Air (wet)>Air (dry)>O₂ (dry)>CO₂ (dry).

### Example 7

### Preparation of an EPG of the Invention

An electric power generator EPG was assembled by using the composition of the active material of Example 6.

Two squared electrodes, respectively made of Cu and Al and having the same area (about 25 cm²) were cleaned and etched in order to be used for assembling the electric power generator. The active material containing oxides powders with average diameter in the range from 10 nm to 40 μm, preferably in the range of 1-10 μm, more preferably 2-5 μm as sold by Sigma-Aldrich was then deposited on the surface of Cu electrode with doctor blade technique. The thickness of the active material was about 500 μm. The product so obtained was baked at a range of temperature from 60° C. to 100° C., preferably from 70° C. to 90° C. for a period of time in the range of 30 minutes to 12 hours, preferably 2 hours in order to dry the active material, thus obtaining a solid electric power generator. After this step, the electrode of Al was placed on top of the deposited active material in a parallel way with respect to the Cu electrode. The two electrodes were gently pressed together assuring a uniform contact of the active material with their own surface.

The used oxygen-containing compound and hence the active material contained coordinated water in the range from 0.5% by weight to 7.5% by weight with respect to oxygen-containing compound, preferably from 0.5% to 3.5%, more preferably from 0.5% to 1.5%.

### Example 8

### Preparation of an EPG of the Invention

An electric power generator EPG was assembled by using the composition of the active material of example 6.

Two squared electrodes, respectively made of Cu and Al and having the same area (about 25 cm²) were cleaned and etched in order to be used for assembling the electric power generator. The active material containing oxides powders with average diameter in the range from 10 nm to 40 μm, preferably in the range of 1-10 μm, more preferably 2-5 μm as sold by Sigma-Aldrich was then deposited on the surface of Cu electrode with spin coating technique accelerating the substrate from 0 to 1000 rpm for 30 seconds and further 60 seconds at 1000 rpm.

The product so obtained was baked at a range of temperature from 60° C. to 120° C., preferably from 80° C. to 100° C. for a period of time in the range of 30 minutes to 12 hours, preferably 2 hours in order to dry the active material, thus obtaining a solid electric power generator. After this step, the electrode of Al was placed on top of the deposited active material in a parallel way with respect to the Cu electrode. The two electrodes were gently pressed together assuring a uniform contact of the active material with their own surface.

The used oxygen-containing compound and hence the active material contained coordinated water in the range from 0.5% by weight to 7.5% by weight with respect to oxygen-containing compound preferably from 0.5% to 3.5%, more preferably from 0.5% to 1.5%.

### Example 9

### Preparation of an Active Material of an EPG of the Invention

In a typical procedure, Mg-methoxide (6-10 wt % solution in methanol) is employed as a precursor. Dry methanol, acetic acid and monoethanolamine are used respectively as a solvent and stabilizers. Mg-methoxide (2-10 mL) was diluted in dry methanol (4-12 mL) while acetic acid (0.02-0.1 mL, ratio AA/alkoxyde 0.1-0.5) and monoethanolamine (0.01-0.05 mL) were added to dry methanol (4-12 mL) in another flask. Then, the acetic acid and monoethanolamine solution was added to the Mg precursor solution, followed by reaction for 0.5-4 h. The MgO solution was then sonicated at 50° C. for 5-30 minutes and followed by heating, stirring and ageing for 12-24 h. The as obtained gel can be applied on the metal electrode by simple dip coating or spin coating techniques and thermally treated at 180-700° C., preferably 200-500° C., more preferably 250-450° C. Thermal treatment duration ranges 5-100 minutes, preferably 5-30 minutes, more preferably 5-20 minutes. The counter electrode can be applied on the gel-coated electrode before the thermal treatment or after the thermal treatment itself.

Without being bound to any theory the inventors deem that fluxing different selected gaseous species during the preparation procedure could enhance the final performances of the as obtained EPG, in terms of OCV, according to the series N₂>Air (wet)>Air (dry)>O₂ (dry)>CO₂ (dry).

### Example 10

### Electrical Characterization of an EPG of the Invention

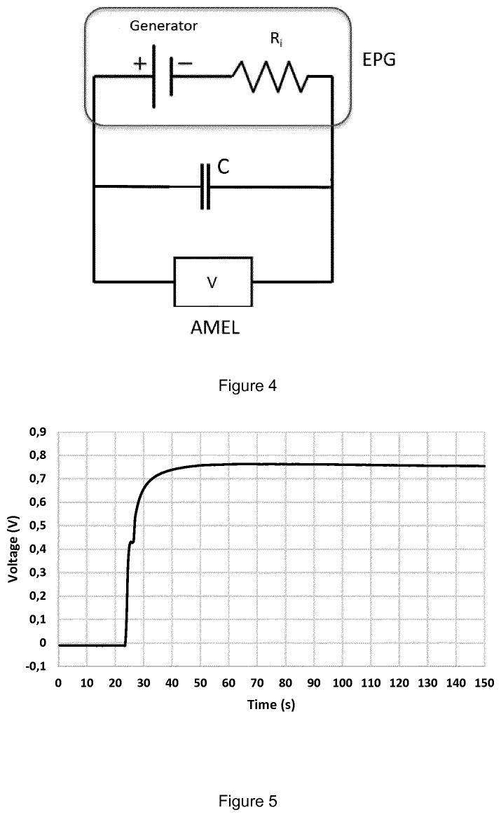

The EPG of Example 2 was electrically characterized by using AMEL2553 potentiostat/galvanostat. The electrical circuit is shown in FIG. 4. More in detail, FIG. 4 shows the EPG, providing a current in, coupled with its own internal resistance (Ri). The latter is normally defined as a ratio between the open circuit potential and the short circuit current. The EPG was connected in series to a capacitor of 10 μF and the voltage of the capacitor was monitored by connecting the galvanostat parallel to it. The source resistance (Ri) is strongly dependent on the components of the active material. The active material resulted to have a low conductivity. The electric power generator was characterized by running a potentiometric analysis setting a null current (open voltage). The result is shown in FIG. 5. Referring to the latter, it can be seen that after 35 s the capacitor was charged up to 760 mV, corresponding to 8 10⁻¹⁰ Wh.

### Example 11

### Thermal Characterization of an EPG of the Invention.

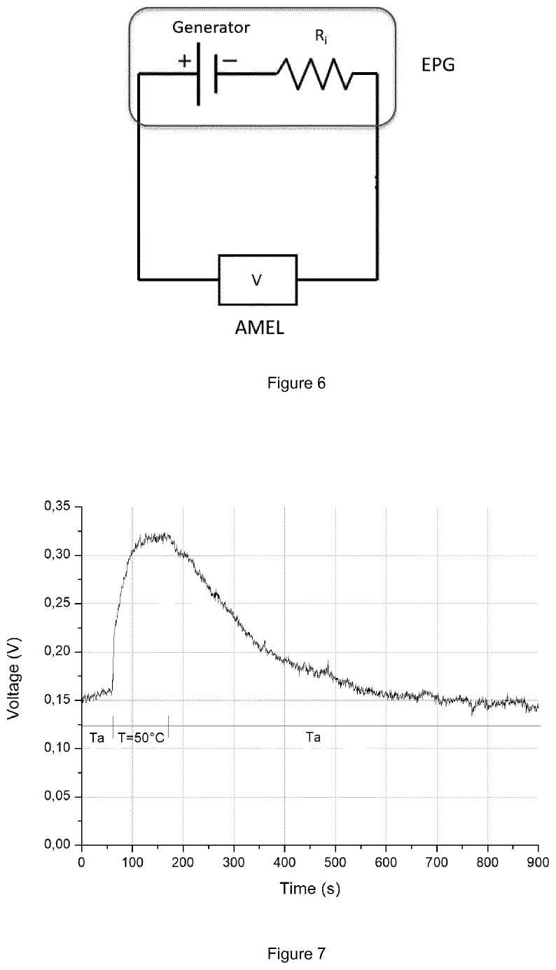

The electric power generator of Example 3 was tested at different temperatures using the circuit scheme reported in FIG. 6. The test lasted 900 seconds. During its first 60 seconds, an open voltage measurement at ambient temperature (i.e. 18° C.) has been performed. Then, the EPG was heated at temperature equal to 50° C. This temperature was kept constant for 100 seconds. After this time interval, the EPG was cooled down in ambient temperature (Ta). The OCV was monitored for all the experiment duration. The experiment has been performed using AMEL2553 potentiostat/galvanostat.

The curve reported in FIG. 7 was obtained. The measured open voltage at temperature equal to 50° C. is 1.5 times higher with respect to the initial value. After the time interval at 50° C., the OCV decreased gradually with the decrease of temperature.

### Example 12

### Electrical Characterization of an EPG of the Invention

The possibility of working with alternate discharge has been evaluated for an EPG having the features as in the Example 1, namely thickness, active medium, composition, electrodes material, electrodes area as in the Example 1. For this test, an electrical circuit as in FIGS. 2A 2B has been used. In said circuit, a load resistance R_{L} of 10 Ohm has been provided. The alternate discharge comprises 5 minutes of working and 5 minutes of rest. However, different ON-OFF times can be applied. In the 5 minutes of working the circuit is closed and capacitor is charged by the EPG. In the 5 minutes of rest, the circuit is open and the capacitor is discharged by load resistance R_{L}. The expression “ON STATE” wants to indicate a working period in which capacitor is charged. In the specific case, this condition occurred cyclically every 5 minutes. For the following 5 minutes, the capacitor was disconnected (OFF STATE) from the EPG and discharged by the R_{L}.

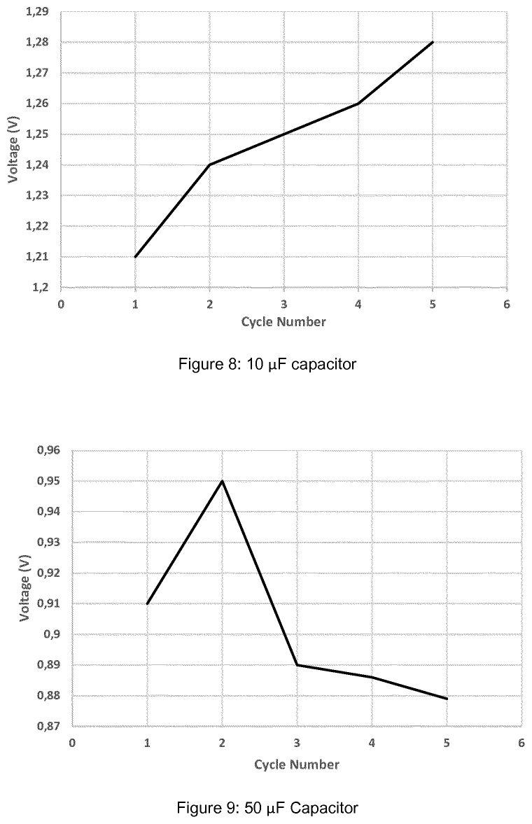

This kind of experiment was performed on both 10 μF and 50 μF capacitors. FIG. 8 and FIG. 9 show the OCV values for the capacitor immediately at the beginning of the OFF state for the 10 μF and 50 μF capacitor respectively.

TABLE 1

| Capacitor | Average OCV [V] | Wh | Wh/L | Wh/Kg |
|---|---|---|---|---|
| 10 μF | 1.25 | 2.16E−09 | 1.38E−05 | 6.07E−06 |
| 50 μF | 0.9 | 5.66E−09 | 3.61E−05 | 1.59E−05 |

Considering values listed in Table 1, it can be noticed that increasing the capacity of the capacitor five times, the relative supplied energy is almost 2.6 times higher. It is clear that the circuit has a strong influence on the EPG performances.

### Example 13

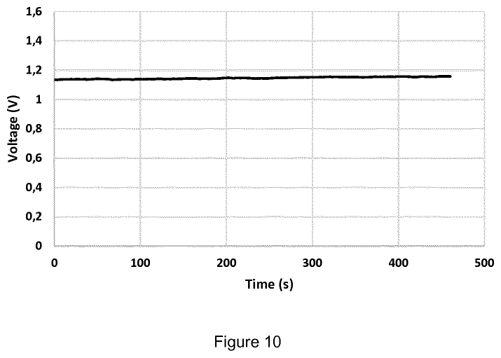

The electric power generator of Example 2 was tested by using AMEL2553 potentiostat/galvanostat in the open circuit voltage (OCV) detection. The circuit scheme is reported in FIG. 6. The OCV measure over time is shown in the FIG. 10 in which it is possible to see that the OCV value is stable in time at 1.135 V.

### Example 14

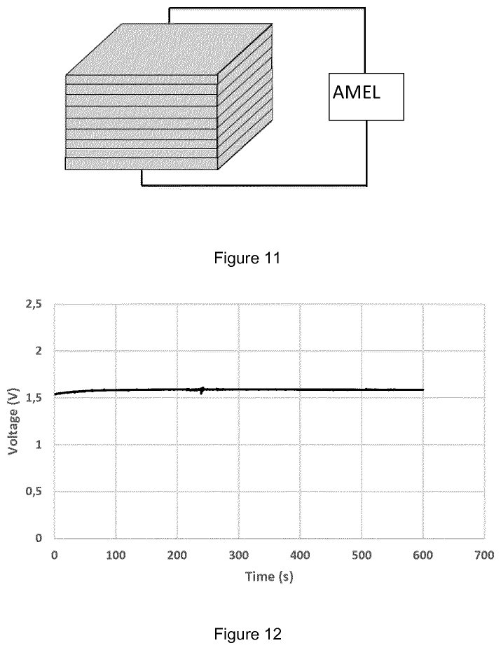

In order to demonstrate the possibility to have a Power Generator Module (PGM) able to supply higher power values, three EPGs fabricated according to Example 1 were connected in series. The open circuit voltage was monitored with AMEL2553 potentiostat/galvanostat. The electrical circuit is reported in FIG. 11. FIG. 12 shows that the OCV value at room temperature for three EPGs is constant in time at 1.6 V while the OCV value for the single EPG based on the Example 1 is around 0.5 V.

1.-22. (canceled)

23. An electric power generator (EPG) comprising at least a first electrode (11) and a second electrode (12), wherein the electric power generator comprises an active material between said electrodes (11,12), said active material comprising at least one oxygen-containing compound selected from the group consisting of MgO, ZnO, ZrOCl₂, ZrO₂, SiO₂, Bi₂O₃, Fe₃O₄, Al₂O₃, TiO₂, BeO, CaO, Ga₂O₃, In₂O₃, GeO₂, SnO₂ and PbO₂, wherein the particle size of the oxygen-containing compound has an average diameter in the range from 10 nm to 40 μm and wherein a thickener additive selected from the group consisting of agar agar, xanthan gum, methyl cellulose, and arabic gum is absent and wherein the at least one oxygen-containing compound or a mixture thereof is in an amount in the range from 50% to 100% (w/w) with respect to the amount of the active material.

24. The electric power generator (EPG) of claim 23, wherein a cellulose compound as a thickener agent is absent.

25. The electric power generator (EPG) of claim 23, wherein the at least one oxygen-containing compound selected from the group consisting of MgO, ZnO, ZrOCl₂, ZrO₂, SiO₂, Bi₂O₃, Fe₃O₄, Al₂O₃, TiO₂, BeO, CaO, Ga₂O₃, In₂O₃, GeO₂, SnO₂ and PbO₂ or a mixture thereof is in an amount in the range 50-80% (w/w) with respect to the amount of the active material.

26. The electric power generator (EPG) of claim 23, wherein the at least one oxygen-containing compound of the active material has particle average diameter in the range from 5 nm to 40 μm, preferably in the range of 15 nm-10 μm, more preferably 20 nm-5 μm.

27. The electric power generator (EPG) of claim 23, wherein the at least one oxygen-containing compound of the active material has particle average diameter in the range from 10 to 200 nm, preferably in the range of 15-100 nm, more preferably 20-40 nm.

28. The electric power generator (EPG) of claim 23, wherein the at least one oxygen-containing compound of the active material is MgO, in the range from 0.6% and 100%, preferably in the range of 50% and 80% with respect to the total weight of the active material.

29. The electric power generator (EPG) of claim 23, wherein the at least one oxygen-containing compound of the active material is ZnO or ZrO₂.

30. The electric power generator (EPG) according to claim 23, wherein the active material comprises MgO, ZnO, ZrO₂.

31. The electric power generator (EPG) according to claim 23, wherein the active material comprises also at least one plasticizer additive.

32. The electric power generator according to claim 31, wherein the at least one plasticizer additive is selected from the group consisting of siloxanes, Carnauba Wax, Naphtalene, PVDF, Parylene, PTFE, FEP, PDMS, aqueous based polymers and bio-polymers.

33. The electric power generator according to claim 23, wherein the oxygen-containing compound contains coordinated water in the range from 0.5% by weight to 7.5% by weight with respect to oxygen-containing compound, preferably from 0.5% to 3.5%, more preferably from 0.5% to 1.5%.

34. The electric power generator (EPG) according to claim 23, wherein said electrodes are made of the different materials in form of powders or metal foils.

35. The electric power generator (EPG) according to claim 23, wherein said electrodes are made of the same material.

36. The electric power generator (EPG) according to claim 34, wherein said first electrode (11) is made of copper and wherein said second electrode is made of aluminum.

37. The electric power generator (EPG) according to claim 35, wherein said electrodes are made of copper.

38. The electric power generator (EPG) according to claim 35, wherein said electrodes are made of aluminum.

39. The electric power generator (EPG) according to claim 35, wherein said electrodes are made of graphite.

40. The electric power generator (EPG) according to claim 34, wherein said electrodes are made of a material selected in a group consisting of metals, alloys and carbon-based materials.

41. A power generator module (PGM) characterized in that it comprises a plurality of electric power generators (EPGs) according to claim 23, wherein said generators are connected in parallel or in series.

42. An electric circuit (EC) comprising an EPG according to claim 23, wherein said circuit (EC) also comprises, a capacitor (C), a resistor (R_{L}) and a switch (SW) and wherein:
in a first switching state, said switch (SW) connects said capacitor (C) in series with said EPG; and
in a second switching state, said switch (SW) connects said capacitor (C) in series with said resistor (R_{L}).

43. An electric circuit (EC) comprising an PGM according to claim 41, wherein said circuit (EC) also comprises, a capacitor (C), a resistor (R_{L}) and a switch (SW) and wherein:
in a first switching state, said switch (SW) connects said capacitor (C) in series with said PGM; and
in a second switching state, said switch (SW) connects said capacitor (C) in series with said resistor (R_{L}).

44. A capacitor (C) comprising at least a first electrode (11) and a second electrode (12), wherein the capacitor comprises an active material between said electrodes (11,12), said active material comprising at least one oxygen-containing compound selected from the group consisting of MgO, ZnO, ZrOCl₂, ZrO₂, SiO₂, Bi₂O₃, Fe₃O₄, Al₂O₃, TiO₂, BeO, CaO, Ga₂O₃, In₂O₃, GeO₂, SnO₂ and PbO₂, wherein the particle size of the oxygen-containing compound has an average diameter in the range from 10 nm to 40 μm and wherein a thickener additive selected from the group consisting of agar agar, xanthan gum, methyl cellulose, and arabic gum is absent.
